(19) United States
(12) Patent Application Publication
(10) Pub. No.: US 2008/0102597 A1
(43) Pub. Date: May 1, 2008

(54) Method for Preparing a Gate Oxide Layer

(75) Inventors: Su Chen Lai, Hsinchu City (TW); Andy Wu, Hsinchu City (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES, INC., Hsinchu (TW)

(21) Appl. No.: 11/615,847

(22) Filed: Dec. 22, 2006

(30) Foreign Application Priority Data
Oct. 25, 2006 (TW) 095139293

(51) Int. Cl. H01L 21/76

(52) U.S. Cl. 438/424

(57) ABSTRACT

A method for preparing a gate oxide layer first forms a mask layer including at least one opening on a semiconductor substrate, and forms a trench in the semiconductor substrate below the opening, wherein the trench surrounds an active area. The opening is enlarged to expose a portion of the semiconductor substrate at the sides of the trench, i.e., to expose the edge of the active area, and an implanting process is then performed to implant nitrogen-containing dopants into the exposed semiconductor substrate below the enlarged opening. Subsequently, the mask layer is removed to expose the semiconductor substrate in the active area, and a thermal treating process is performed to form a gate oxide layer on the upper surface of the semiconductor substrate in the active area. The nitrogen-containing dopants can inhibit the reaction rate of the thermal oxidation of the semiconductor substrate during the thermal treating process.

### BACKGROUND OF THE INVENTION

(A) Field of the Invention

The present invention relates to a method for preparing a gate oxide layer, and more particularly, to a method for preparing a gate oxide layer capable of preventing the incremental increase in thickness of the gate oxide layer at the edge of an active area.

(B) Description of the Related Art

In conventional semiconductor fabrication processes, the local oxidation of silicon (LOCOS) or shallow trench isolation (STI) is widely adopted to electrically isolate electronic elements on the wafer so as to avoid shorts circuit caused by the interference of electronic elements. As the field oxide layer formed by LOCOS occupies a larger area on the wafer and meanwhile the bird's beak phenomenon occurs, current advanced semiconductor fabrication processes often adopt STI to electrically isolate the electronic elements.

FIG. 1 illustrates a shallow trench isolation 10 according to the prior art. The shallow trench isolation 10 surrounds an active area 20, and a gate oxide layer 14 is formed on the surface of the silicon substrate 12 in the active area 20. Along with the continuous downsizing of the semiconductor element, the width of the active area 20 is also decreased, which results in the bird's beak phenomenon at the edge of the active area 20, i.e. the gate oxide layer 14 has a larger thickness at the edge of the active area 20 than at the center of the active area 20.

### SUMMARY OF THE INVENTION

One aspect of the present invention provides a method for preparing a gate oxide layer, which uses an implanting process to implant nitrogen-containing dopants into the silicon substrate of the active area, in which nitrogen-containing dopants can inhibit the reaction rate of the thermal oxidation to prevent the gate oxide layer having a greater thickness at the edge of the active area than at the center of the active area.

A method for preparing a gate oxide layer according to this aspect of the present invention first forms a mask layer having at least one opening on a semiconductor substrate, and performs an anisotropic dry etching process to form a trench in the semiconductor substrate below the opening, wherein the trench surrounds an active area. A wet etching process is carried out to enlarge the opening to expose a portion of the semiconductor substrate at the sides of the trench, i.e., to expose the edge of the active area, and an implanting process is then performed to implant nitrogen-containing dopants into the semiconductor substrate below the opening. Subsequently, the mask layer is removed to expose the semiconductor substrate in the active area, and a first thermal treating process is performed to form a gate oxide layer on the upper surface of the semiconductor substrate in the active area.

The nitrogen-containing dopants can inhibit the thermal oxidation rate of the semiconductor substrate during the first thermal treating process, and the nitrogen-containing dopants are selectively implanted into the semiconductor substrate at the sides of the trench, i.e., into the edge of the active area. Consequently, when the thermal treating process is carried out to form the gate oxide layer, the oxidation rate of the semiconductor substrate at the sides of the trench is slower, i.e., the oxidation rate at the edge of the active area is slower, while the oxidation rate at the center of the active area is relatively faster, thus preventing the gate oxide layer having a larger thickness at the edge of the active area than at the center of the active area.

### BRIEF DESCRIPTION OF THE DRAWINGS

The objectives and advantages of the present invention will become apparent upon reading the following description and upon reference to the accompanying drawings in which:

FIG. 1 illustrates a shallow trench isolation according to the prior art; and

FIGS. 2-8 illustrate a method for preparing a gate oxide layer according to the present invention.

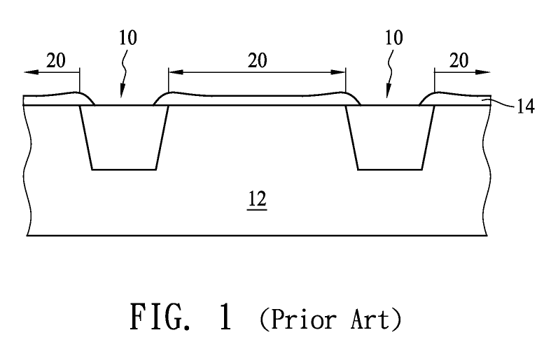

### DETAILED DESCRIPTION OF THE INVENTION

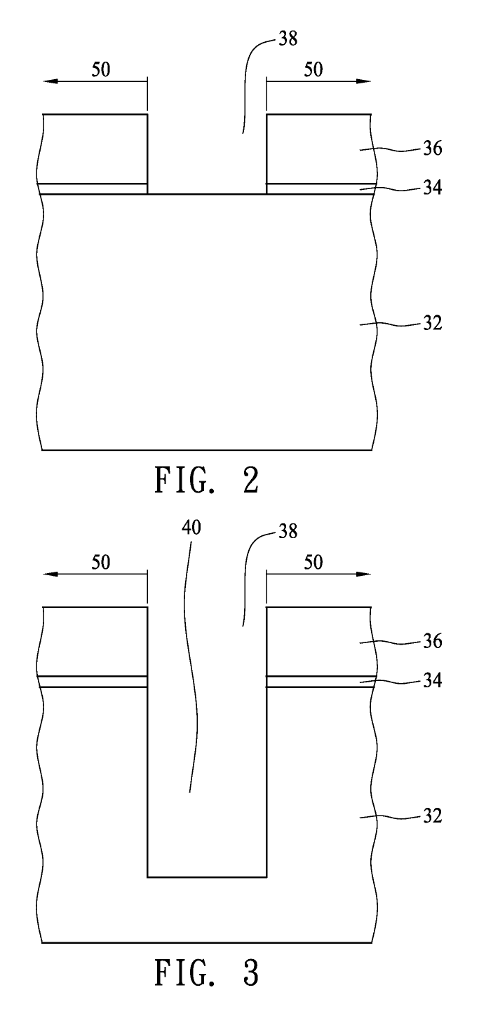

FIG. 2 to FIG. 8 illustrate a method for preparing a gate oxide layer 48 according to the present invention. First, a pad oxide layer 34 and a mask layer 36 made of silicon nitride are formed on a silicon substrate 32 successively, wherein the mask layer 36 has an opening 38. An anisotropic dry etching process is then performed to remove a portion of the silicon substrate 32 below the opening 38 to form a trench 40, wherein the trench 40 surrounds an active area 50, as shown in FIG. 3.

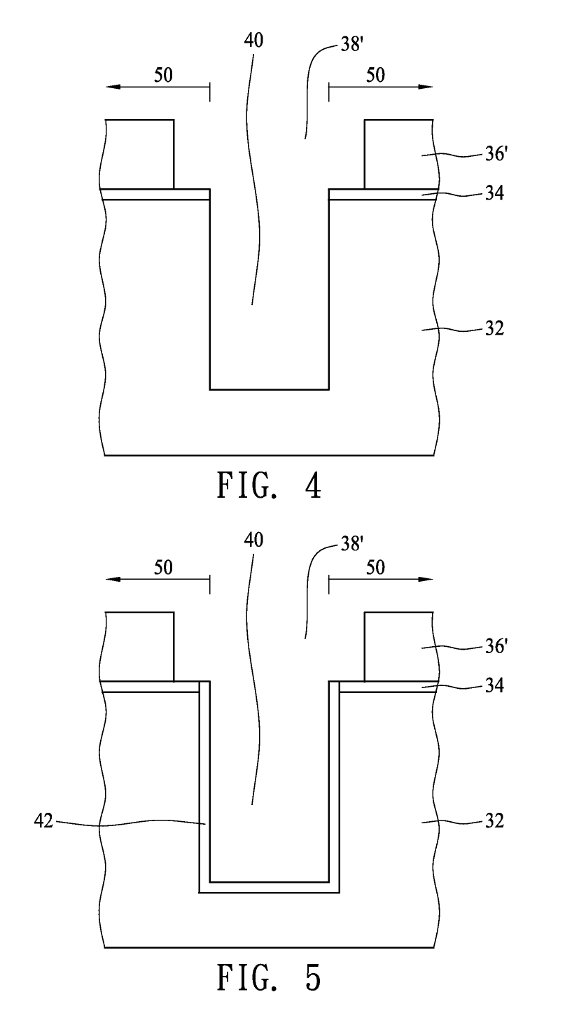

Referring to FIG. 4, an etching solution containing hot phosphoric acid is used to perform a wet etching process to remove a portion of the mask layer 36 at the sides of the trench 40 so as to form an implanting mask 36′, i.e., enlarging the opening 38 to form an opening 38′, which exposes a portion of the silicon substrate 32 at the sides of the trench 40. Preferably, the exposed width of the semiconductor substrate 32 at the sides of the trench 40 by the opening 38′ ranges from 130 angstroms to 200 angstroms. A thermal treating process is then carried out to form a liner oxide layer 42, which covers the exposed silicon substrate 32, i.e., the sidewalls and bottom surface of the trench 40, as shown in FIG. 5. Briefly, the processes shown in FIG. 2 to FIG. 4 are used to form the trench 40 in the silicon substrate 32 and form the implanting mask 36′ on the silicon substrate 32, and the opening 38′ exposes a portion of the silicon substrate 32 at the sides of the trench 40, i.e., exposes the edge of the active area 50.

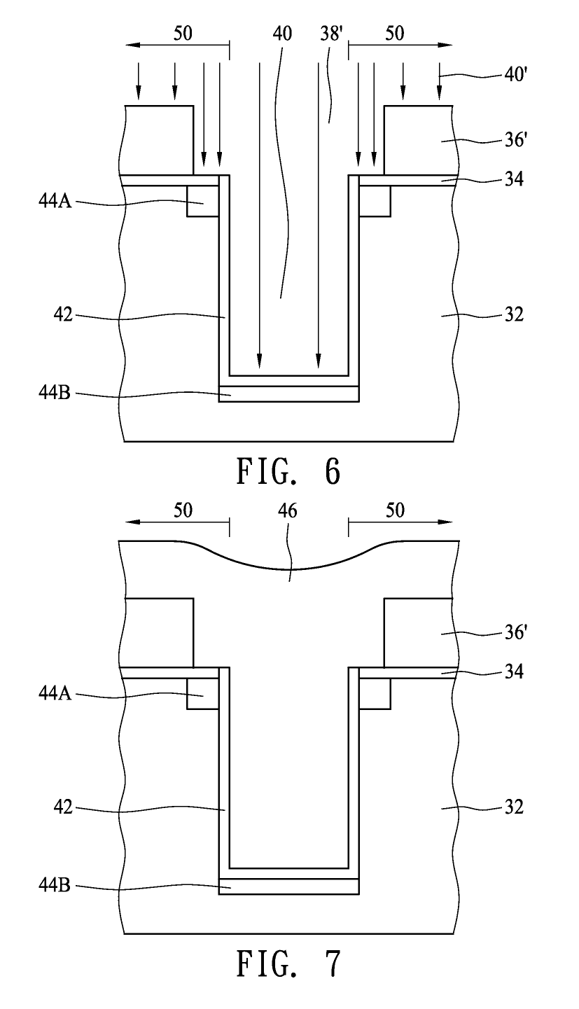

Referring to FIG. 6, an implanting process is performed to implant nitrogen-containing dopants 40′ into the silicon substrate 32 below the opening 38′. Through the implanting process, the nitrogen-containing dopants 40′ are implanted into the silicon substrate 32 at the sides of the trench 40 to form a doped region 44A and into the silicon substrate 32 below the trench 40 to form a doped region 44B. Preferably, the nitrogen-containing dopants 40′ can be ions selected from a group consisting of nitrogen atom, nitrogen gas, nitrous oxide and nitric oxide. Afterwards, a chemical vapor deposition (CVD) process is performed to uniformly create a dielectric layer 46 filling the trench 40, as shown in FIG. 7.

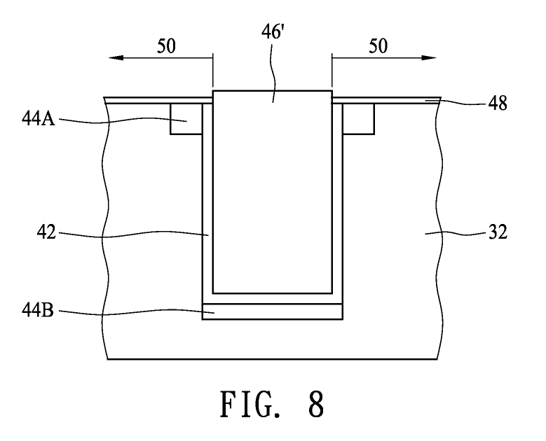

Referring to FIG. 8, a planarization process, for example, chemical mechanical polishing process, is carried out to remove a portion of the dielectric layer 46 above the implanting mask 36′, so as to form a dielectric block 46′ in the trench 40. An etching solution containing hot phosphoric acid is used to perform a wet etching process to completely remove the implanting mask 36′ and a hydrofluoric acid solution is then used to perform a wet etching process to completely remove the pad oxide layer 34 so as to expose the surface of the silicon substrate 32 in the active area 50. Thereafter, a thermal oxidation process is performed to form a gate oxide layer 48 on the surface of the silicon substrate 32 in the active area 50.

The nitrogen-containing dopants 40′ can inhibit the thermal oxidation rate of the semiconductor substrate 32 during the thermal treating process, and the nitrogen-containing dopants 40′ are selectively implanted into the semiconductor substrate 32 at the sides of the trench 40, i.e., into the edge of the active area 50. Consequently, when the thermal treating process is carried out to form the gate oxide layer 48, the oxidation rate of the semiconductor substrate 32 at the sides of the trench 40 is slower, i.e., the oxidation rate at the edge of the active area 50 is slower, while the oxidation rate in the center of the active area 50 is relatively faster, thus preventing the gate oxide layer 48 having a greater thickness at the edge of the active area 50 than in the center of the active area 50.

The above-described embodiments of the present invention are intended to be illustrative only. Numerous alternative embodiments may be devised by those skilled in the art without departing from the scope of the following claims.

What is claimed is:

1. A method for preparing a gate oxide layer, comprising the steps of:
forming a mask layer on a semiconductor substrate, wherein the mask layer has at least one opening;
forming a trench in the semiconductor substrate having an active area, wherein the trench is below the opening and surrounds an active area;
enlarging the opening to expose a portion of the semiconductor substrate at sides of the trench;
performing an implanting process to implant nitrogen-containing dopants into the semiconductor substrate below the enlarged opening; and
performing a first thermal treating process to form a gate oxide layer on an upper surface of the active area.

2. The method for preparing a gate oxide layer as claimed in claim 1, further comprising performing a second thermal treating process to form a liner oxide layer covering sidewalls and a bottom surface of the trench before the implanting process.

3. The method for preparing a gate oxide layer as claimed in claim 1, further comprising performing a chemical vapor deposition process to form a dielectric layer filling in the trench.

4. The method for preparing a gate oxide layer as claimed in claim 1, wherein the width of the enlarged opening ranges from 130 angstroms to 200 angstroms.

5. The method for preparing a gate oxide layer as claimed in claim 1, wherein the nitrogen-containing dopants are ions of nitrogen atoms.

6. The method for preparing a gate oxide layer as claimed in claim 1, wherein the nitrogen-containing dopants are ions of nitrogen gases.

7. The method for preparing a gate oxide layer as claimed in claim 1, wherein the nitrogen-containing dopants are ions of nitrous oxide.

8. The method for preparing a gate oxide layer as claimed in claim 1, wherein the nitrogen-containing dopants are ions of nitric oxide.

9. The method for preparing a gate oxide layer as claimed in claim 1, wherein the mask layer comprises silicon nitride, and the opening is enlarged by a wet etching process using a wet etching solution containing phosphoric acid.

10. The method for preparing a gate oxide layer as claimed in claim 1, wherein the semiconductor substrate is a silicon substrate.

11. A method for preparing a gate oxide layer, comprising the steps of:
forming a trench in a semiconductor substrate having an active area, wherein the trench surrounds the active area;
forming an implanting mask on the semiconductor substrate, wherein the implanting mask has an opening exposing a portion of the semiconductor substrate at sides of the trench;
performing an implanting process to implant nitrogen-containing dopants into the semiconductor substrate below the opening; and
performing a first thermal treating process to form a gate oxide layer on an upper surface of the active area.

12. The method for preparing a gate oxide layer as claimed in claim 11, further comprising performing a second thermal treating process to form a liner oxide layer covering sidewalls and a bottom surface of the trench before the implanting process.

13. The method for preparing a gate oxide layer as claimed in claim 11, further comprising performing a chemical vapor phase deposition process to form a dielectric layer filling the trench.

14. The method for preparing a gate oxide layer as claimed in claim 11, wherein the width of the semiconductor substrate at the sides of the trench exposed by the opening ranges from 130 angstroms to 200 angstroms.

15. The method for preparing a gate oxide layer as claimed in claim 11, wherein the nitrogen-containing dopants are ions of nitrogen atoms.

16. The method for preparing a gate oxide layer as claimed in claim 11, wherein the nitrogen-containing dopants are ions of nitrogen gases.

17. The method for preparing a gate oxide layer as claimed in claim 11, wherein the nitrogen-containing dopants are ions of nitrous oxide.

18. The method for preparing a gate oxide layer as claimed in claim 11, wherein the nitrogen-containing dopants are ions of nitric oxide.

19. The method for preparing a gate oxide layer as claimed in claim 11, wherein the implanting mask comprises silicon nitride.

20. The method for preparing a gate oxide layer as claimed in claim 11, wherein the semiconductor substrate is a silicon substrate.
